(19) United States
(12) Patent Application Publication
(10) Pub. No.: US 2025/0357296 A1
(43) Pub. Date: Nov. 20, 2025

(54) CAPACITOR INTEGRATED PASSIVE DEVICE WITH COMMON GROUNDED THROUGH-SUBSTRATE-VIA AND SUBSTRATE BACKSIDE CONDUCTOR AND METHODS OF FORMING THE SAME

(71) Applicant: Taiwan Semiconductor Manufacturing Company Limited, Hsinchu (TW)

(72) Inventors: Shin-Puu Jeng, Hsinchu (TW); Monsen Liu, Hsinchu (TW); Shuo-Mao Chen, New Taipei City (TW)

(21) Appl. No.: 18/666,902

(22) Filed: May 17, 2024

(51) Int. Cl. H01L 23/498; H01L 21/48; H01L 21/768; H01L 23/522; H01L 23/528; H01L 29/94

(52) U.S. Cl. CPC H01L 23/49827; H01L 21/486; H01L 21/76898; H01L 23/49816; H01L 23/5223; H01L 23/528; H01L 23/5283; H01L 23/5286; H10D 1/665

(57) ABSTRACT

An embodiment integrated passive device may include a substrate, a deep trench capacitor formed within the substrate, electrical interconnect structures formed on a first side of the substrate and electrically connected to the deep trench capacitor, and an electrically conducting through-substrate-via formed within the substrate and extending from the first side of the substrate to a second side of the substrate and electrically connected to one or more of the electrical interconnect structures formed on the first side of the substrate. The electrical interconnect structures may be connected to one or more power terminals and to one or more ground terminals of the deep trench capacitor, and the through-substrate-via may be electrically connected to the second interconnects on the first side of the substrate. The integrated passive device may further include an electrical contact structure formed on the second side of the substrate that is electrically connected to the through-substrate-via.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens, hundreds, or thousands of integrated circuits are typically manufactured on a single semiconductor wafer, and individual dies on the wafer may be singulated by sawing (i.e., dicing) between the integrated circuits along scribe lines. The individual dies are typically packaged separately, in multi-chip modules, or in other types of packaging, for example.

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Chips (SoIC) devices. Some of these three-dimensional devices (e.g., 3DIC, SoC, SoIC) are prepared by placing chips over chips on a semiconductor wafer level. These three-dimensional devices provide improved integration density and other advantages, such as faster speeds and higher bandwidth, because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a vertical cross-sectional view of a semiconductor device including semiconductor dies and an integrated passive device attached to an interposer, according to various embodiments.

FIG. 1B is a horizontal cross-sectional view of the semiconductor device of FIG. 1, according to various embodiments.

FIG. 1C is a vertical cross-sectional view of a further semiconductor device including semiconductor dies and integrated passive device dies attached to an interposer, according to various embodiments.

FIG. 1D is a vertical cross-sectional view of a portion of the semiconductor device of FIG. 1C showing details of an integrated passive device, according to various embodiments.

FIG. 2 is a vertical cross-sectional view of a portion of a further semiconductor device, according to various embodiments.

FIG. 3A is a vertical cross-sectional view of a portion of a further semiconductor device having shorter electrical pathways than those of the semiconductor device of FIG. 2, according to various embodiments.

FIG. 3B is a vertical cross-sectional view of a portion of a further semiconductor device having shorter electrical pathways than those of the semiconductor device of FIG. 2, according to various embodiments.

FIG. 3C is a top view of the portion of the semiconductor device of FIG. 3B, according to various embodiments.

FIG. 4A is a vertical cross-sectional view of an integrated passive device, according to various embodiments.

FIG. 4B is a vertical cross-sectional view of a further integrated passive device, according to various embodiments.

FIG. 4C is a vertical cross-sectional view of a further integrated passive device, according to various embodiments.

FIG. 4D is a vertical cross-sectional view of a further integrated passive device, according to various embodiments.

FIG. 4E is a vertical cross-sectional view of a further integrated passive device, according to various embodiments.

FIG. 5A is a vertical cross-sectional view of an intermediate structure that may be used in the formation of an integrated passive device, according to various embodiments.

FIG. 5B is a vertical cross-sectional view of a further intermediate structure that may be used in the formation of an integrated passive device, according to various embodiments.

FIG. 5C is a vertical cross-sectional view of a further intermediate structure that may be used in the formation of an integrated passive device, according to various embodiments.

FIG. 5D is a vertical cross-sectional view of a further intermediate structure that may be used in the formation of an integrated passive device, according to various embodiments.

FIG. 5E is a vertical cross-sectional view of a further intermediate structure that may be used in the formation of an integrated passive device, according to various embodiments.

FIG. 5F is a vertical cross-sectional view of a further intermediate structure that may be used in the formation of an integrated passive device, according to various embodiments.

FIG. 5G is a vertical cross-sectional view of a further intermediate structure that may be used in the formation of an integrated passive device, according to various embodiments.

FIG. 5H is a vertical cross-sectional view of a further intermediate structure that may be used in the formation of an integrated passive device, according to various embodiments.

FIG. 5I is a vertical cross-sectional view of a further intermediate structure that may be used in the formation of an integrated passive device, according to various embodiments.

FIG. 6A is a vertical cross-sectional view of an intermediate structure that may be used in the formation of an integrated passive device, according to various embodiments.

FIG. 6B is a vertical cross-sectional view of a further intermediate structure that may be used in the formation of an integrated passive device, according to various embodiments.

FIG. 6C is a vertical cross-sectional view of a further intermediate structure that may be used in the formation of an integrated passive device, according to various embodiments.

FIG. 6D is a vertical cross-sectional view of a further intermediate structure that may be used in the formation of an integrated passive device, according to various embodiments.

FIG. 6E is a vertical cross-sectional view of a further intermediate structure that may be used in the formation of an integrated passive device, according to various embodiments.

FIG. 6F is a vertical cross-sectional view of a further intermediate structure that may be used in the formation of an integrated passive device, according to various embodiments.

FIG. 7A is a vertical cross-sectional view of an intermediate structure that may be used in the formation of an integrated passive device, according to various embodiments.

FIG. 7B is a vertical cross-sectional view of a further intermediate structure that may be used in the formation of an integrated passive device, according to various embodiments.

FIG. 7C is a vertical cross-sectional view of a further intermediate structure that may be used in the formation of an integrated passive device, according to various embodiments.

FIG. 7D is a vertical cross-sectional view of a further intermediate structure that may be used in the formation of an integrated passive device, according to various embodiments.

FIG. 7E is a vertical cross-sectional view of a further intermediate structure that may be used in the formation of an integrated passive device, according to various embodiments.

FIG. 7F is a vertical cross-sectional view of a further intermediate structure that may be used in the formation of an integrated passive device, according to various embodiments.

FIG. 7G is a vertical cross-sectional view of a further intermediate structure that may be used in the formation of an integrated passive device, according to various embodiments.

FIG. 7H is a vertical cross-sectional view of a further intermediate structure that may be used in the formation of an integrated passive device, according to various embodiments.

FIG. 7I is a vertical cross-sectional view of a further intermediate structure that may be used in the formation of an integrated passive device, according to various embodiments.

FIG. 8A is a vertical cross-sectional view of an intermediate structure that may be used in the formation of an integrated passive device, according to various embodiments.

FIG. 8B is a vertical cross-sectional view of a further intermediate structure that may be used in the formation of an integrated passive device, according to various embodiments.

FIG. 8C is a vertical cross-sectional view of a further intermediate structure that may be used in the formation of an integrated passive device, according to various embodiments.

FIG. 8D is a vertical cross-sectional view of a further intermediate structure that may be used in the formation of an integrated passive device, according to various embodiments.

FIG. 8E is a vertical cross-sectional view of a further intermediate structure that may be used in the formation of an integrated passive device, according to various embodiments.

FIG. 8F is a vertical cross-sectional view of a further intermediate structure that may be used in the formation of an integrated passive device, according to various embodiments.

FIG. 8G is a vertical cross-sectional view of a further intermediate structure that may be used in the formation of an integrated passive device, according to various embodiments.

FIG. 8H is a vertical cross-sectional view of a further intermediate structure that may be used in the formation of an integrated passive device, according to various embodiments.

FIG. 8I is a vertical cross-sectional view of a further intermediate structure that may be used in the formation of an integrated passive device, according to various embodiments.

FIG. 9A is a vertical cross-sectional view of an IPD that is held by a pick-and-place tool, according to various embodiments.

FIG. 9B is a further vertical cross-sectional view of the IPD that is held by the pick-and-place tool of FIG. 9A, according to various embodiments.

FIG. 9C is a vertical cross-sectional view of an IPD that is held by an alternative pick-and-place tool in a comparative embodiment.

FIG. 9D is a further vertical cross-sectional view of the IPD that is held by the pick-and-place tool of FIG. 9C.

FIG. 9E is a further vertical cross-sectional view of the IPD that is held by the pick-and-place tool of FIG. 9C.

FIG. 10 is a flowchart illustrating operations of a method of forming an integrated passive device, according to various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein may be advantageous by providing an integrated passive device (IPD) having a through-substrate-via that provides a common electrical ground connection on a first side and on a second side of the IPD. As such, the IPD may be electrically connected to an interposer on the first side of the IPD and electrically connected to a package substrate on the second side of the IPD. The direct electrical connections on both the first side and the second side of the IPD provide ground electrical pathways having shorter lengths than corresponding electrical pathways in IPDs that only provide electrical connections on the first side of the IPD. Such shorter electrical pathways may provide reduced electrical loss and lower signal delays by reducing an RC time constant associated with the shorter electrical pathways.

An embodiment integrated passive device may include a substrate, a deep trench capacitor formed within the substrate, electrical interconnect structures formed on a first side of the substrate and electrically connected to the deep trench capacitor, and an electrically conducting through-substrate-via formed within the substrate and extending from the first side of the substrate to a second side of the substrate and electrically connected to one or more of the electrical interconnect structures formed on the first side of the substrate. The electrical interconnect structures may be connected to one or more power terminals and to one or more ground terminals of the deep trench capacitor, and the through-substrate-via may be electrically connected to the second interconnects on the first side of the substrate. The integrated passive device may further include an electrical contact structure formed on the second side of the substrate that is electrically connected to the through-substrate-via.

According to a further embodiment, a semiconductor package structure may include an interposer, a package substrate, and an integrated passive device (IPD) sandwiched therebetween, and electrically connected to, the interposer and the package substrate. The IPD may include an IPD substrate, a deep trench capacitor formed within the IPD substrate, and an electrically conducting through-substrate-via formed within the IPD substrate. The electrically conducting through-substrate-via may extend from a first side of the IPD substrate to a second side of the IPD substrate such that the through-substrate-via is electrically connected to the deep trench capacitor on the first side of the IPD substrate and is electrically connected to the package substrate on the second side of the IPD substrate.

According to a further embodiment, a method of forming an integrated passive device may include forming a deep trench capacitor in a substrate; forming electrical interconnect structures on a first side of the substrate; coupling electrical interconnect structures to the deep trench capacitor; forming an electrically conducting through-substrate-via within the substrate such that the through-substrate-via extends from the first side of the substrate to a second side of the substrate; and coupling the through-substrate-via to one or more of the electrical interconnect structures formed on the first side of the substrate.

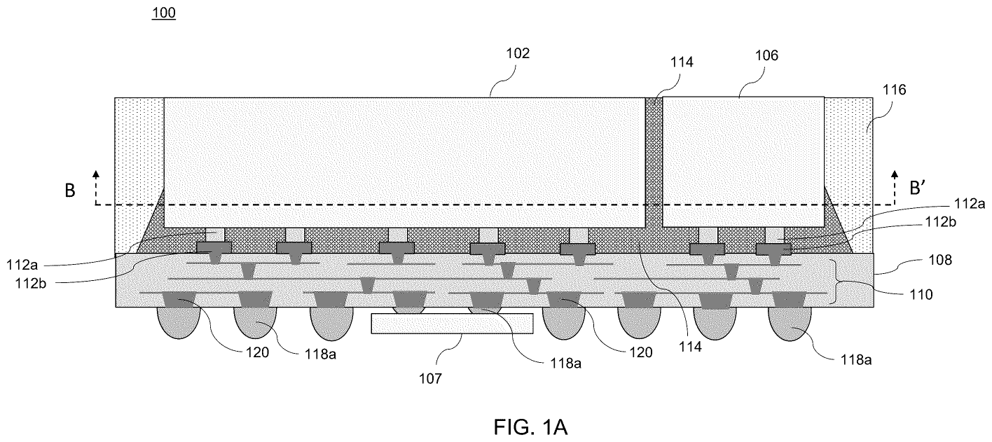

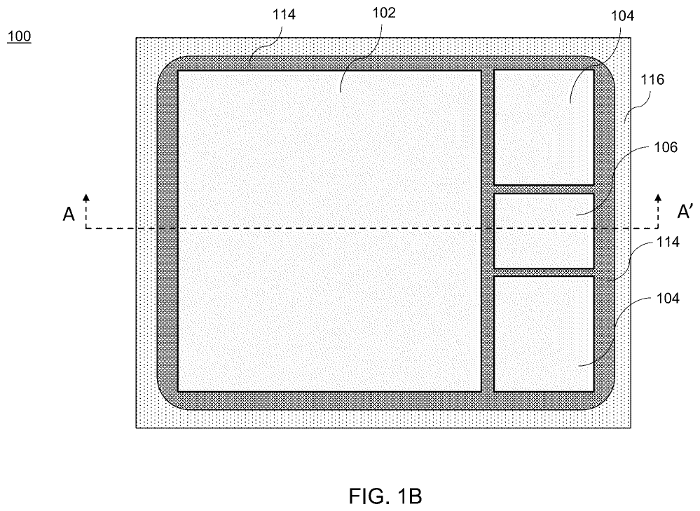

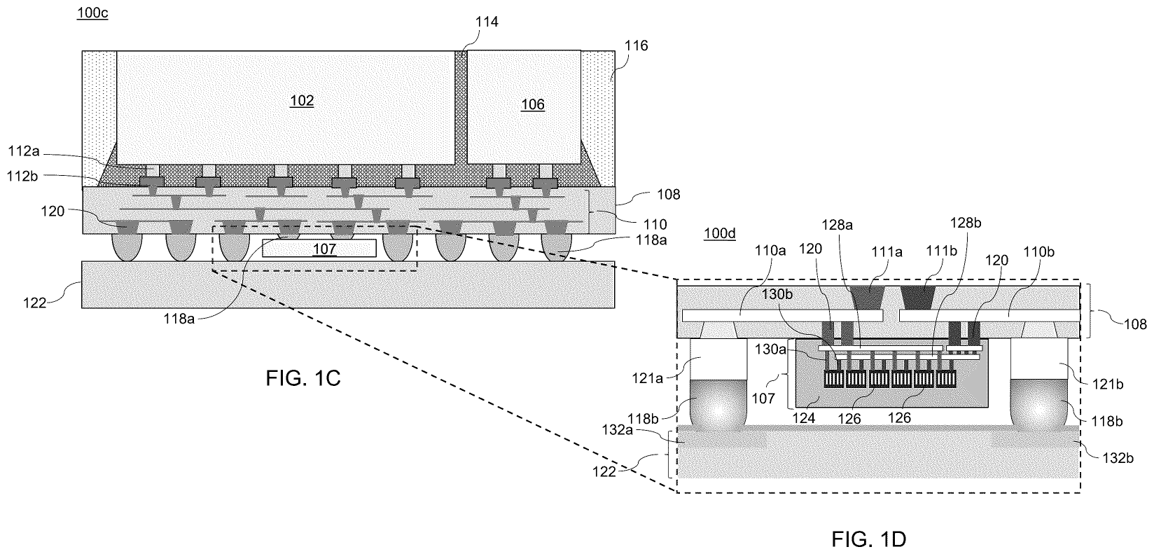

FIG. 1A is a vertical cross-sectional view of a semiconductor device 100 including semiconductor dies (102 and 104 shown in FIG. 1B) and integrated passive devices (106, 107) electrically connected to an interposer 108, and FIG. 1B is a horizontal cross-sectional view of the semiconductor device 100 of FIG. 1, according to various embodiments. The cross-sectional view of FIG. 1A corresponds to a vertical plane indicated by the cross-section A-A′ in FIG. 1B, and the cross-sectional view of FIG. 1B corresponds to a horizontal plane indicated by the cross-section B-B′ in FIG. 1A. As shown, in FIGS. 1A and 1B, the semiconductor device 100 may include a first semiconductor die 102, two second semiconductor dies 104, and one or more integrated passive devices (106, 107). More or fewer semiconductor dies 102, 104, and integrated passive device 106, 107 may be used. According to an embodiment, the first semiconductor die 102 may be a system-on-chip (SoC) die and the second semiconductor dies 104 may each be high-bandwidth memory (HBM) dies. In other embodiments, the first semiconductor die 102 and the two second semiconductor dies 104 may be various other types of dies that may be configured to provide various functionalities.

As shown, in FIG. 1A, a first integrated passive device 106 may be attached to a first side of the interposer 108 along with the first semiconductor die 102 and the two second semiconductor dies 104. In other embodiments, a second integrated passive device 107 may be attached to a second side of the interposer 108 opposite the first semiconductor die 102 and the two second semiconductor dies 104. As shown, in FIG. 1A, some embodiments may include both the first integrated passive device 106 and the second integrated passive device 107. However, other embodiments (not shown) may include only one of the first integrated passive device 106 and the second integrated passive device 107.

The interposer 108 may be an organic interposer, a silicon interposer, a glass interposer, etc., having a redistribution interconnect structure 110. The first semiconductor die 102, the second semiconductor dies 104, and the integrated passive devices (106, 107) may each be electrically coupled to the interposer 108 with a plurality of solder portions (e.g., first solder portions 118) that connect respective bonding pads or micro-bumps of the respective semiconductor devices (102, 104) and integrated passive devices (106, 107) and the interposer 108. For example, the first semiconductor die 102 and the first integrated passive device 106 may each include first bonding pads 112a that may be configured to be attached to respective second bonding pads 112b of the interposer 108, as shown in FIG. 1A. The second semiconductor die 104 may include similar first bonding pads (not shown). As such, the second semiconductor die 104 may similarly be electrically coupled to the interposer 108 via a plurality of solder portions (not shown) that connect respective bonding pads or micro-bumps (not shown) of the respective second semiconductor die 104 and the interposer 108.

At least one underfill material portion 114 may be formed around the first bonding pads 112a and second bonding pads 112b. The underfill material portion 114 may be formed by injecting an underfill material around the first bonding pads 112a and second bonding pads 112b after solder material portions (not shown) are reflowed. Various underfill material application methods may be used, which may include, for example, a capillary underfill method, a molded underfill method, or a printed underfill method. In this example embodiment, the respective semiconductor dies (102, 104) and integrated passive devices (106, 107) may be attached to the interposer 108 and a single underfill material portion 114 may continuously extend underneath first semiconductor die 102, the second semiconductor dies 104, and the first integrated passive device 106, as shown in FIGS. 1A and 1B.

An epoxy molding compound (EMC) may be applied to gaps formed over the interposer 108 and around the respective semiconductor dies (102, 104) and integrated passive devices (106, 107) to thereby form an EMC frame 116. The EMC may include an epoxy-containing compound that may be hardened (i.e., cured) to provide a dielectric material portion having sufficient stiffness and mechanical strength. The EMC may include epoxy resin, hardener, silica (as a filler material), and other additives. The EMC may be provided in a liquid form or in a solid form depending on the viscosity and flowability. Liquid EMC may provide better handling, good flowability, fewer voids, better fill, and fewer flow marks. Solid EMC provides less cure shrinkage, better stand-off, and less die drift. A high filler content (such as 85% in weight) within an EMC may shorten the time in mold, lower the mold shrinkage, and reduce the mold warpage. Uniform filler size distribution in the EMC may reduce flow marks and may enhance flowability.

The EMC may be cured at a curing temperature to form an EMC matrix that laterally encloses each of the respective semiconductor dies (102, 104) and integrated passive devices (106, 107). The curing temperature of the EMC may be in a range from 125° C. to 150° C. The EMC frame 116 may laterally surround and embed the respective semiconductor dies (102, 104) and integrated passive devices (106, 107). Excess portions of the EMC frame 116 may be removed from above the horizontal plane including the top surfaces of the respective semiconductor dies (102, 104) and integrated passive devices (106, 107) by a planarization process, which may use chemical mechanical planarization. In other embodiments, a similar EMC matrix (not shown) may be formed between a top surface of the second integrated passive device 107 and a bottom surface of the interposer 108.

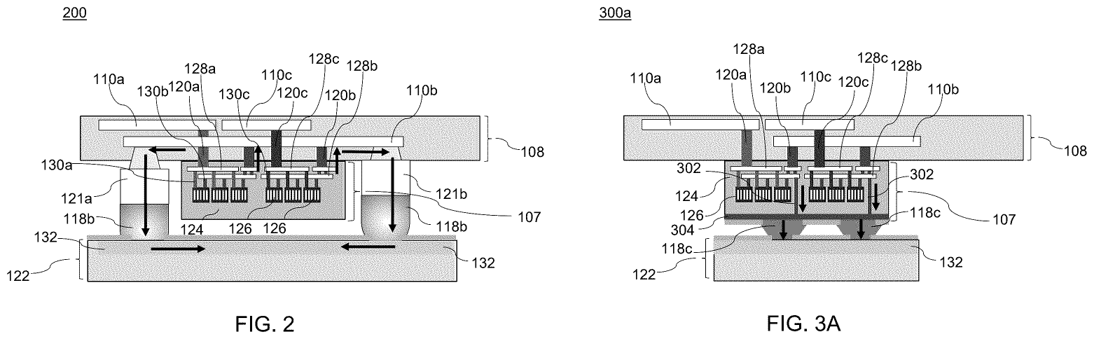

The semiconductor device 100, including the first semiconductor die 102, the second semiconductor dies 104, the first integrated passive device 106, and the interposer 108, may further be coupled to a package substrate 122 (e.g., see FIG. 1C) by the first solder portions 118 (e.g., 118a, 118b) that may couple bonding pads 120 (or bump structures) of the interposer 108 and the package substrate 122. The substrate may further be electrically coupled to another structure such as a printed circuit board PCB (not shown) via respective bonding pads (or bump structures) of the substrate and PCB. The integrated passive device 106 may be configured in various ways, as described with reference to FIGS. 2A and 2B, below.

FIG. 1C is a vertical cross-sectional view of a further semiconductor device 100c including semiconductor dies (102, 104) and IPDs (106, 107) attached to an interposer 108, according to various embodiments. The semiconductor device 100c may be formed from the semiconductor device 100 of FIGS. 1A and 1B, by attaching and coupling the interposer 108 of the semiconductor device 100 to a package substrate 122. In this regard, the semiconductor device 100 of FIGS. 1A and 1B may be aligned over the package substate 122 such that electrically conducting pads (not shown) of the package substrate 122 are aligned with first solder material portions 118a of the semiconductor device 100. A reflow process may then be performed to melt the first solder portions 118a. Upon cooling, the first solder portions 118a may solidify to thereby form electrical/mechanical connections between the interposer 108 and the package substrate 122. The package substrate 122 may include electrical interconnect structures (not shown) that may provide electrical power, electrical ground connections, and electrical signal pathways to the interposer 108. In turn, the interposer 108 may provide such electrical connections to the semiconductor dies (102, 104) and IPDs (106, 107) that are electrically and mechanically coupled to the interposer 108. The package substrate 122 may then be connected with other circuit components, such as a PCB (not shown).

FIG. 1D is a vertical cross-sectional view of a portion 100d of the semiconductor device 100c of FIG. 1C showing details of an IPD 107, according to various embodiments. In this regard, as shown in FIG. 1D, the portion 100d of the semiconductor device 100c of FIG. 1C may include a lower portion of the interposer 108, an upper portion of the package substrate 122, and the IPD 107 that is electrically and mechanically connected to the lower portion of the interposer 108. The IPD 107 may include an IPD substrate 124 having a plurality of deep trench capacitors 126 formed therein.

The IPD 107 may include a plurality of electrical interconnect structures (128a, 128b) formed on a first side (e.g., a top side) of the IPD substrate 124. As shown, the interconnect structures (128a, 128b) may be electrically connected to the deep trench capacitors 126. In this regard, the plurality of electrical interconnect structures (128a, 128b) may include first interconnects 128a connected to one or more power terminals 130a of the deep trench capacitors 126 and second interconnects 128b connected to one or more ground terminals 130b of the deep trench capacitors 126. Further, the first interconnects 128a may be connected to first redistribution interconnects 110a and the second interconnects 128b may be connected to second redistribution interconnects 110b of the redistribution interconnect structure 110 (e.g., see FIG. 1C) of the interposer 108.

As described above with reference to FIGS. 1A and 1C, the plurality of electrical interconnect structures (128a, 128b) of the IPD 107 may be electrically connected to respective redistribution interconnects (110a, 110b) through bonding pads 120 (or bump structures) formed respectively on the IPD 107 and the interposer 108. In this regard, electrical and mechanical connections may be formed by first solder material portions 118a (e.g., see FIG. 1C) formed between respective bonding pads 120 (or bump structures) of the IPD 107 and the interposer 108. The redistribution interconnect structure 110 may further include first vias 111a and second vias 111b that may be respectively connected to the first redistribution interconnects 110a and the second redistribution interconnects 110b. In this regard, the power and ground connections may be shared with other interconnects and vias (not shown) of the interposer 108, such that power voltages and ground voltages may be transferred to the semiconductor dies (102, 104) and the IPD 106 connected to the interposer 108 on the opposite side of the interposer 108 from the IPD 107 as shown, for example, in FIG. 1C.

As further shown in FIG. 1D, the interposer 108 may be electrically and mechanically connected to the package substrate 122 with a first bump structure 121a and a second bump structure 121b. In this regard, second solder material portions 118b may be provided between the bump structures (121a, 121b) and respective package substrate bonding pads (132a, 132b). In this regard, a first package substrate bonding pad 132a may be electrically and mechanically connected to the first bump structure 121a and a second package substrate bonding pad 132b may be electrically and mechanically connected to the second bump structure 121b. As such, the first package substrate bonding pad 132a may be configured as a power terminal of the package substrate 122 and the second package substrate bonding pad 132b may be a ground terminal of the package substrate 122.

FIG. 2 is a vertical cross-sectional view of a portion of a further semiconductor device 200, according to various embodiments. The semiconductor device 200 of FIG. 2 may be similar to the semiconductor device 100 of FIG. 1D but may further include multiple power interconnects (110a, 110c) and a common ground connection 132 formed in the package substrate 122. In this regard, the semiconductor device 200 may include a first interconnects 128a connected to one or more first power terminals 130a of the deep trench capacitors 126 and second interconnects 128b connected to one or more ground terminals 130b of the deep trench capacitors 126. In contrast to the semiconductor device 100c, however, the semiconductor device 200 of FIG. 2 may further include third interconnects 128c connected to second power terminals 130c of the deep trench capacitors 126.

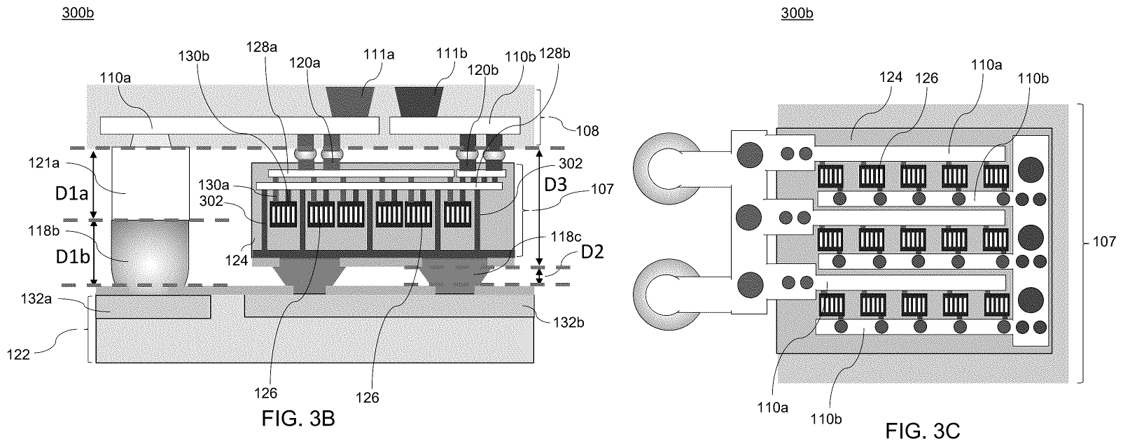

Each of the first interconnects 128a, the second interconnects 128b, and the third interconnects 128c may be connected to respective first redistribution interconnects 110a, second redistribution interconnects 110b, and third redistribution interconnects 110c of the interposer 108. As shown, the second redistribution interconnects 110b may be configured as a common ground interconnect that may be electrically connected to the common ground connection 132 of the package substrate 122 through the bump structures (121a, 121b). Electrical pathways that provide a common ground connection between the IPD 107 and the package substrate 122 are indicated by the arrows in FIG. 2. Longer electrical pathways give rise to increased electrical resistance and RC time constant signal delays. Further embodiments that provide shorter electrical pathways between the IPD 107 and the package substrate, such as those described below with reference to FIGS. 3A to 3C may therefore be advantageous by reducing signal delay and loss.

FIG. 3A is a vertical cross-sectional view of a portion of a further semiconductor package structure 300a having shorter electrical pathways than those of the semiconductor device 200 of FIG. 2, according to various embodiments. As shown in FIG. 3A, the semiconductor package structure 300a may include an interposer 108, a package substrate 122, and an IPD 107 sandwiched therebetween, and electrically connected to, the interposer 108 and the package substrate 122. The IPD 107 may include an IPD substrate 124, one or more deep trench capacitors 126 formed within the IPD substrate 124, and one or more electrically conducting through-substrate-vias 302 formed within the IPD substrate 124. As shown in FIG. 3A, the through-substrate-via 302 may extend from a first side (e.g., the top side) of the IPD substrate to a second side (e.g., the bottom side) of the IPD substrate 124 such that the through-substrate-via 302 is electrically connected to the deep trench capacitor 126 on the first side of the IPD substrate 124 and is electrically connected to the package substrate 122 on the second side of the IPD substrate 124.

As with the semiconductor device 200, described above with reference to FIG. 2, the IPD 107 may further include electrical interconnect structures (128a, 128b, 128c) formed on the first side of the IPD substrate 124, which are electrically connected to the deep trench capacitors 126. The IPD 107 may further include micro-bump electrical contacts (120a, 120b, 120c) that may be electrically connected to the electrical interconnect structures (128a, 128b, 128b), such that the micro-bump electrical contacts (120a, 120b, 120c) are electrically connected to the interposer 108. In this regard, the micro-bump electrical contacts (120a, 120b, 120c) may be connected to corresponding respective micro-bump electrical contacts (120a, 120b, 120c) formed on the interposer 108 such that the micro-bump electrical contacts (120a, 120b, 120c) are connected to corresponding redistribution interconnect structures (110a, 110b, 110c) of the interposer 108.

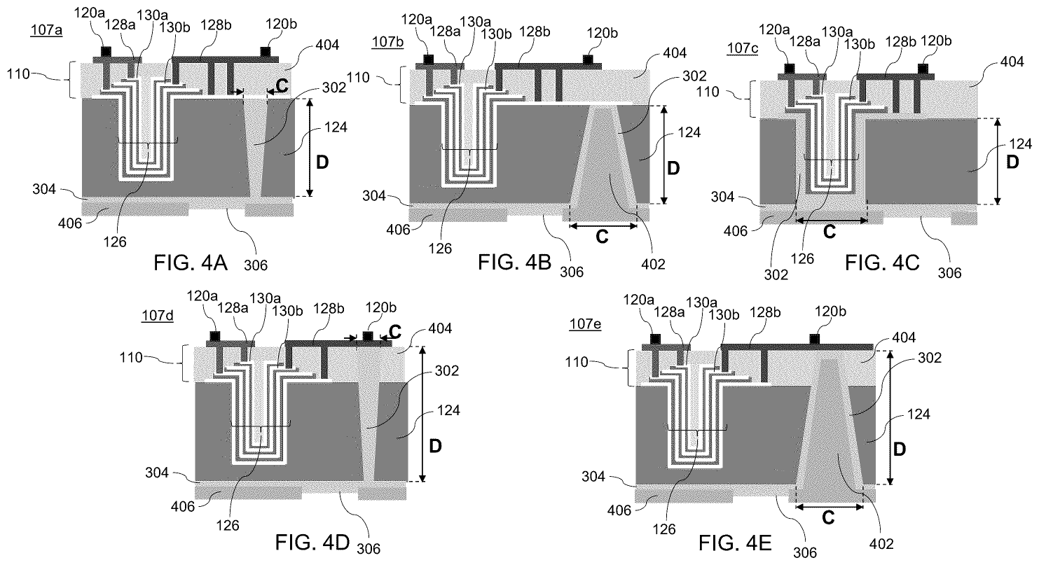

As shown in FIG. 3A, the IPD 107 may further include an electrically conducting material layer 304 formed on the second side of the IPD 107 substrate that is formed in direct contact with the IPD substrate 124 and that is electrically connected to the through-substrate-via 302. The IPD 107 may further include an electrical contact structure 306 (e.g., see FIG. 4A) formed on the second side of the IPD substrate 124 that is electrically connected to the through-substrate-via 302. As such, the IPD 107 may be electrically and mechanically connected to the package substrate 122 by forming a third solder material portion 118c between the electrical contact structure 306 of the IPD 107 and a corresponding package substrate electrical contact (e.g., the common ground connection 302) such that the IPD 107 is electrically connected to the package substrate 122. As indicated by the arrows in FIG. 3A, a common ground electrical connection may be formed between the interposer 108, the IPD 107, and the package substrate 122, in which the electrical pathways have shorter lengths than corresponding electrical pathways (e.g., see arrows) of the semiconductor device 200 of FIG. 2.

FIG. 3B is a vertical cross-sectional view of a portion of a further semiconductor package structure 300b having shorter electrical pathways than those of the semiconductor device 200 of FIG. 2, according to various embodiments. As shown in FIG. 3B, the semiconductor package structure 300a may include an interposer 108, a package substrate 122, and an IPD 107 sandwiched therebetween, and electrically connected to, the interposer 108 and the package substrate 122. The IPD 107 may include an IPD substrate 124, one or more deep trench capacitors 126 formed within the IPD substrate 124, and one or more electrically conducting through-substrate-vias 302 formed within the IPD substrate. The IPD 107 may further include electrical interconnect structures (128a, 128b) including first interconnects 128a connected to one or more power terminals 130a of the one or more deep trench capacitors 126 and second interconnects 128b connected to one or more ground terminals 130b of the one or more deep trench capacitor 126.

The IPD 107 may further include micro-bump electrical contacts (120a, 120b) that may be respectively to the first interconnects 128a and the second interconnects 128b. First electrical contacts (e.g., first micro-bump structures 120a) may be electrically connected to a power contact (e.g., first redistribution interconnects 110a) of the interposer 108 and second electrical contacts (e.g., second micro-bump structures 120b) may be connected to a ground contact (e.g., second redistribution interconnects 110b) of the interposer 108. As such, the second redistribution interconnects 110b may be configured as a first ground connection for the IPD 107, located on the first side of the IPD 107. The first redistribution interconnects 110a may further be connected to a power contact 132a of the package substrate through a connection provided by first bump structure 121a. As shown, the first bump structure 121a may be electrically and mechanically connected to a first package substrate bonding pad 132a, which may be configured as a power contact, by a second solder material portion 118b.

A second ground connection for the IPD 107 may be provided by the one or more through-substrate-vias 302. In this regard, the electrical contact structure 306 (e.g., see FIG. 4A) of the IPD 107 may be electrically connected to a second package substrate bonding pad 132b, which may be configured as a ground contact of the package substrate. For example, as shown in FIG. 3B, the electrical contact structure 306 (e.g., see FIG. 4A) of the IPD 107 may be electrically and mechanically connected to the second package substrate bonding pad 132b by third solder material portions 118c. As such, the IPD 107 may be connected to a second ground contact (i.e., the second package substrate bonding pad 132b) of the package substrate 122 such that the interposer 108, the IPD 107, and the package substrate 122 form a common ground connection that is electrically connected to the one or more through-substrate-via 302.

As shown in FIG. 3B, the first bump structure 121a may have a thickness D1a and the second solder material portion 118b may have a thickness D1b. The sum D1a+D1b may be between 120 microns and 150 microns. As shown, the thickness D1a of the first bump structure 121a may be less than that of the second solder material portion 118b (i.e., D1a<D1b). However, in various other embodiments, the thickness D1a of the first bump structure 121a may be greater than that of the second solder material portion 118b (i.e., D1a>D1b), or the thicknesses of the first bump structure 121a and the second solder material portions 118b may approximately equal (i.e., D1a˜ D1b). A separation between the IPD 107 and package substrate 122 may have a thickness D2 that is between 60 microns and 100 microns. Similarly, a distance D3 between a bottom surface of the interposer 108 and a bottom surface of the IPD 107 may be between 80 microns and 100 microns.

FIG. 3C is a top view of the portion of the semiconductor package structure 300b of FIG. 3B, according to various embodiments. As shown in FIG. 3C, a plurality of deep trench capacitors 126 may be formed in the IPD substrate 124 and may be arranged in parallel rows. Further, the first redistribution interconnects 110a and the second redistribution interconnects 110b may arranged as alternating parallel structures that may be respectively attached to respective sides of each of the plurality of deep trench capacitors 126. The configuration of deep trench capacitors 126 and redistribution interconnect structures (110a, 110b) shown in FIG. 3C represents only one possible configuration for the IPDs 107. Various other configurations may be provided in other embodiments.

FIGS. 4A to 4E are vertical cross-sectional views of IPDs (107a, 107b, 107c, 107d, 107e), according to various embodiments. Each of the embodiment IPDs (107a, 107b, 107c, 107d, 107e) may include an IPD substrate 124, a deep trench capacitor 126 formed within the IPD substrate 124, electrical interconnect structures (128a, 128b) formed on a first side (i.e., the top side) of the IPD substrate 124 and electrically connected to the deep trench capacitor 126. Each of the embodiment IPDs (107a, 107b, 107c, 107d, 107e) may further include an electrically conducting through-substrate-via 302 formed within the IPD substrate 124 and extending from the first side (i.e., the top side) of the substrate to a second side (i.e., the bottom side) of the IPD substrate 124. As shown in FIGS. 4A to 4E, the through-substrate-via 302 may be electrically connected to one or more of the electrical interconnect structures 128b formed on the first side of the IPD substrate 124. The various embodiment IPDs (107a, 107b, 107c, 107d, 107e) may correspond to various configurations of the through-substrate-via 302, as described in further detail below.

As described above, the electrical interconnect structures (128a, 128b) may further include first interconnects 128a connected to one or more power terminals 130a of the deep trench capacitor 126 and second interconnects 128b connected to one or more ground terminals 130b of the deep trench capacitor 126. Further, as shown in FIGS. 4A to 4E, the through-substrate-via 302 may be electrically connected to the second interconnects 128b on the first side of the IPD substrate 124. Further, each of the embodiment IPDs (107a, 107b, 107c, 107d, 107e) may include an electrical contact structure 306 formed on the second side (i.e., on the bottom side) of the IPD substrate 124 that is electrically connected to the through-substrate-via 302. Further, as described above, each of the embodiment IPDs (107a, 107b, 107c, 107d, 107e) may further include an electrically conducting material layer 304 formed on the second side of the IPD substrate 124. In various embodiments, the electrically conducting material layer 304 may be formed so as to be in direct contact with the IPD substrate 124 and to be electrically connected to the through-substrate-via 302.

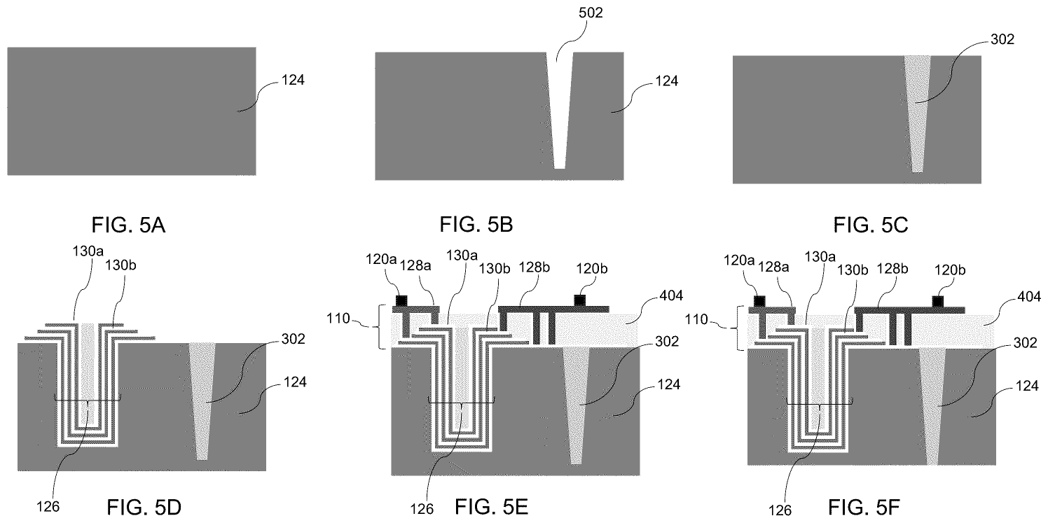

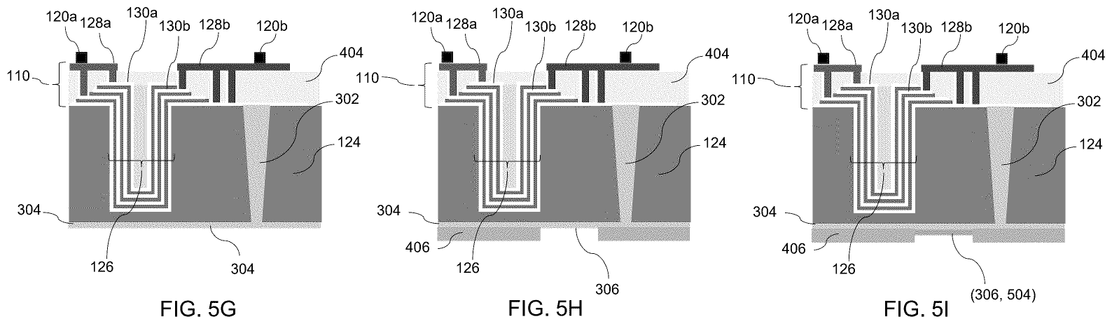

A polymer layer 406 may be formed over the conducting material layer 304, which may act as a solder resist layer. Further, the electrical contact structure 306 may be formed as a portion of the electrically conducting material layer 304 that is exposed by an opening in the polymer layer 406 on the second side of the IPD substrate 124. The electrical contact structure 306 may further include an additional conducting material layer 504 (e.g., see FIG. 5I) formed over the exposed portion of the electrically conducting material layer 304. In various embodiments, the electrically conducting material layer 304 and the through-substrate-via 302 may be formed of copper, aluminum, or another conducting material, and the additional conducting material layer 504 may include tin, nickel, or other plating material.

In certain embodiment IPDs (107a, 107d), the through-substrate-via 302 may be formed as a volume of electrically conducting material extending through the IPD substrate 124 as shown, for example, in FIGS. 4A and 4D. In other embodiment IPDs (107b, 107c, 107d), the through-substrate-via 302 may be formed as a shell structure as shown, for example, in FIGS. 4B, 4C, and 4E. In this regard, as shown in FIG. 4C, the IPD 107c may include a through-substrate-via 302 that is formed as an electrically conducting shell structure around the deep trench capacitor 126 and that extends from the first side of the IPD substrate 124 to the second side of the IPD substrate 124. Alternatively, as shown in FIGS. 4B and 4E, the through-substrate-via 302 may be formed as a composite structure including an electrically conducting shell structure 302 surrounding a dielectric material 402 such as a non-conducting polymer material. Further, in contrast to the IPD 107c of FIG. 4C, each of the electrically conducting shell structures of FIGS. 4B and 4E may be separate and distinct from the deep trench capacitor 126.

As shown in FIGS. 4A to 4E, each of the embodiment IPDs (107a, 107b, 107c, 107d, 107e) may be configured such that the electrical interconnect structures (128a, 128b) are formed as redistribution layers 110. In this regard, a dielectric layer 404 may be formed on the first side (i.e., on the top side) of the IPD substrate 124 in each IPD (107a, 107b, 107c, 107d, 107e) and the electrical interconnect structures (128a, 128b) may be formed within the dielectric layer 404. As shown in FIGS. 4A, 4B, and 4C, in the embodiment IPDs (107a, 107b, 107c) the through-substrate-via 302 may extend from the second side (i.e., the bottom side) of the IPD substrate 124 to the first side (i.e., the top side) of the IPD substrate 124. In further embodiments, as shown in FIGS. 4D and 4E, the through-substrate-via 302 may extend from the second side of the IPD substrate 124, through the first side of the IPD substrate 124, and through at least a portion of the dielectric layer 404 in the embodiment IPDs (107d, 107e). Thus, as shown in FIGS. 4A, 4B, and 4C, the through-substrate-via 302 may be connected to the second interconnect structures 128b on a bottom side of the dielectric layer 404 in IPDs (107a, 107b, 107c), while as shown in FIGS. 4D and 4E, the through-substrate-via 302 may be connected to the second interconnect structures 128b at or near a top side of the dielectric layer 404 in IPDs (107d, 107e).

As shown in FIGS. 4A to 4E, the redistribution interconnect structures 110 may further include micro-bump electrical contacts (120a, 120b) that may be connected to the electrical interconnect structures (128a, 128b), which may, in turn, be electrically connected to respective power terminals 130a and ground terminals 130b of each of the IPDs (107a, 107b, 107c, 107d, 107e). In various embodiments, the IPD substrate 124 in each of the IPDs (107a, 107b, 107c, 107d, 107e) may be a semiconductor such as silicon, germanium, SiGe, GaAs, InGaAs, etc. Further, the through-substrate-via 302 may include an electrically conducting material that is formed in direct contact with the IPD substrate 124.

FIGS. 5A to 5I are vertical cross-sectional views of intermediate structures that may be used in the formation of an IPD 107a, according to various embodiments. The intermediate structure of FIG. 5A may be a semiconductor substrate 124 that may be patterned using lithography techniques to form a via opening 502, as shown in the intermediate structure of FIG. 5B. In this regard, a blanket layer of a photoresist material (not shown) may be formed over the intermediate structure of FIG. 5A. The blanket layer of photoresist may then be patterned using lithographic techniques to generate a patterned photoresist (also not shown). An anisotropic etch process may then be performed to remove a portion of the semiconductor substrate 124, that is not masked by the patterned photoresist, to thereby generate the via opening 502 of FIG. 5B, which may then be filled with a conductive material. A planarization process (e.g., chemical mechanical planarization (CMP)) may then be performed to remove excess portions of conducting material over a top surface of the semiconductor substrate 124 to thereby form the intermediate structure including the through-substrate-via 302 structure, as shown in FIG. 5C.

The conductive material, which may be deposited in the via opening 502 to form the through-substrate-via 302, may be a combination of a metallic liner (such as a metallic nitride or a metallic carbide) and a metallic fill material. The metallic liner may include TiN, TaN, WN, TiC, TaC, and WC, and the metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used.

The intermediate structure of FIG. 5D may be formed from the intermediate structure of FIG. 5C, by forming deep trench capacitor 126 in the semiconductor substrate 124. In this regard, a patterned photoresist (not shown) may be formed over the intermediate structure of FIG. 5C. A portion of the semiconductor substrate 124 not masked by the patterned photoresist may then be etched to form a trench, which may be filled by depositing alternating layers of conductive material and dielectric material to form the deep trench capacitor 126. The intermediate structure of FIG. 5E may then be formed by forming a redistribution layer 110 over the intermediate structure of FIG. 5D. In this regard, a dielectric layer 404 (e.g., a polymer material) may be formed over the surface of the intermediate structure in FIG. 5D. The dielectric layer 404 may then be patterned using lithography techniques to form line trenches and via holes. A metallic material may then be deposited (e.g., by electroplating) over the patterned dielectric layer 404 to thereby form the redistribution interconnect structures (110a, 110b). In some embodiments, a conducting seed layer may be first deposited (e.g., by sputtering) followed by deposition of a metallic material (e.g., copper or a copper/nickel alloy).

The intermediate structure of FIG. 5F may be formed from the intermediate structure of FIG. 5E by performing a grinding operation on the lower side (i.e., the second side) of the semiconductor substrate 124 to expose a lower surface of the through-substrate-via 302. The intermediate structure of FIG. 5G may be formed from the intermediate structure of FIG. 5F by forming an electrically conducting material layer 304 on the second side of the semiconductor substrate 124. As described above, the electrically conducting material layer 304 may be formed to be in direct contact with the IPD substrate 124 and to be electrically connected to the through-substrate-via 302. In this regard, the electrically conducting material layer may be deposited by electroplating or by a vapor phase deposition process (e.g., CVD).

The intermediate structure of FIG. 5H may be formed from the intermediate structure of FIG. 5G by forming the polymer layer 406 over the electrically conducting material layer 304. Various polymers (e.g., polyimide (PI)) may be used to form the polymer layer 406. The polymer layer 406 may be deposited using various techniques such as by performing a spin coating process or by a vapor deposition method. The polymer layer 406 may then be patterned using lithographic techniques to form an opening that exposes a portion of the electrically conducting material layer 304. As described above, the exposed portion of the electrically conducting material layer 304 may be configured as an electrical contact structure 306. The intermediate structure of FIG. 5I may be formed from the intermediate structure of FIG. 5H by forming an additional conducting material layer 504 formed over the exposed portion (i.e., the electrical contact structure 306) of the electrically conducting material layer 304. The additional conducting material layer 504 may include tin, nickel, or other plating material and may be formed by electroplating, sputtering, or other vapor phase deposition technique.

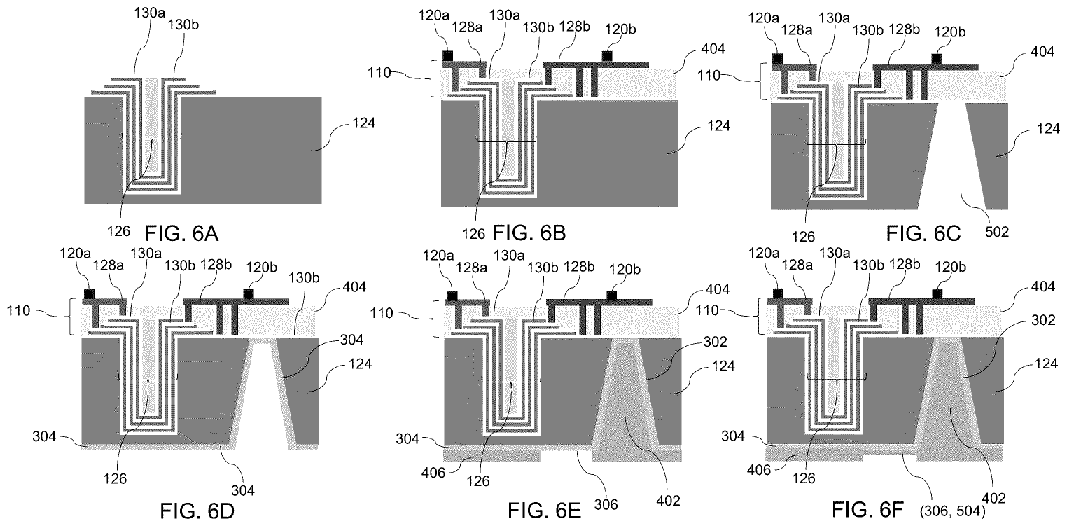

FIGS. 6A to 6F are vertical cross-sectional views of intermediate structures that may be used in the formation of an IPD 107b (e.g., see FIG. 4B), according to various embodiments. As shown in FIG. 6A, the intermediate structure may be formed by first forming a deep trench capacitor structure 126 in a semiconductor substrate 124. As shown, the deep trench capacitor 126 may include power terminals 130a and ground terminals 130b. A redistribution layer 110 may then be formed over a first side (e.g., the top side) of the intermediate structure of FIG. 6A to thereby form the intermediate structure of FIG. 6B. In this regard, as described above with reference to the intermediate structure of FIG. 5E, the redistribution layer 110 may include first interconnects 128a and second interconnects 128b formed in a dielectric layer 404. Further, the first interconnects 128a and the second interconnects 128b may be electrically connected to the power terminals 130a and ground terminals 130b, respectively, of the deep trench capacitor 126.

The intermediate structure of FIG. 6C may then be formed from the intermediate structure of FIG. 6B by forming a via opening 502 in the second side (i.e., the bottom side). In this regard, a patterned photoresist (not shown) may be formed over the second side of the intermediate structure of FIG. 6B and an anisotropic etch process may be performed to remove a portion of the semiconductor substrate 124 that is not masked by the patterned substrate to thereby form the via opening 502. The anisotropic etch process may be allowed to progress such that the via opening 502 extends from the second side to the first side of the semiconductor substrate 124. The intermediate structure of FIG. 6D may then be formed from the intermediate structure of FIG. 6C by forming an electrically conducting material layer 304 over the second side of the intermediate structure of FIG. 6C. In this regard, the electrically conducting material layer 304 may be formed by electroplating or by a vapor deposition process. As shown, the electrically conducting material layer 304 may be formed so as to cover sidewalls of the via opening 502 as well as to cover surfaces of the second side of the semiconductor substrate 124. As such, the electrically conducting material layer 304 may be formed in direct electrical contact with the semiconducting substrate 124. Further, as shown in FIG. 6D, the electrically conducting material layer 304 may make contact with one of the ground contacts 130b of the deep trench capacitor 126.

The intermediate structure of FIG. 6E may then be formed from the intermediate structure of FIG. 6D by depositing a polymer layer 406 over the conducting material layer 304. As shown, the polymer layer 406 may fill the via opening 502 and may cover the conducting material layer 304 that is electroplated or deposited therein. A patterned photoresist layer (not shown) may then be formed over the polymer layer 406. An etching process may then be performed to remove portions of the polymer layer 406 that are not masked by the patterned photoresist. In this regard, an opening may be formed in the polymer layer 406 to thereby expose a portion of the electrically conducting material layer 304. The exposed portion of the electrically conducting material layer 304 may then be configured as an electrical contact structure 306 on the second side of the intermediate structure of FIG. 6E. The intermediate structure of FIG. 6F may be formed from the intermediate structure of FIG. 6E by forming an additional conducting material layer 504 formed over the exposed portion (i.e., the electrical contact structure 306) of the electrically conducting material layer 304. The additional conducting material layer 504 may include tin, nickel, or other plating material and may be formed by electroplating, sputtering, or other vapor phase deposition technique.

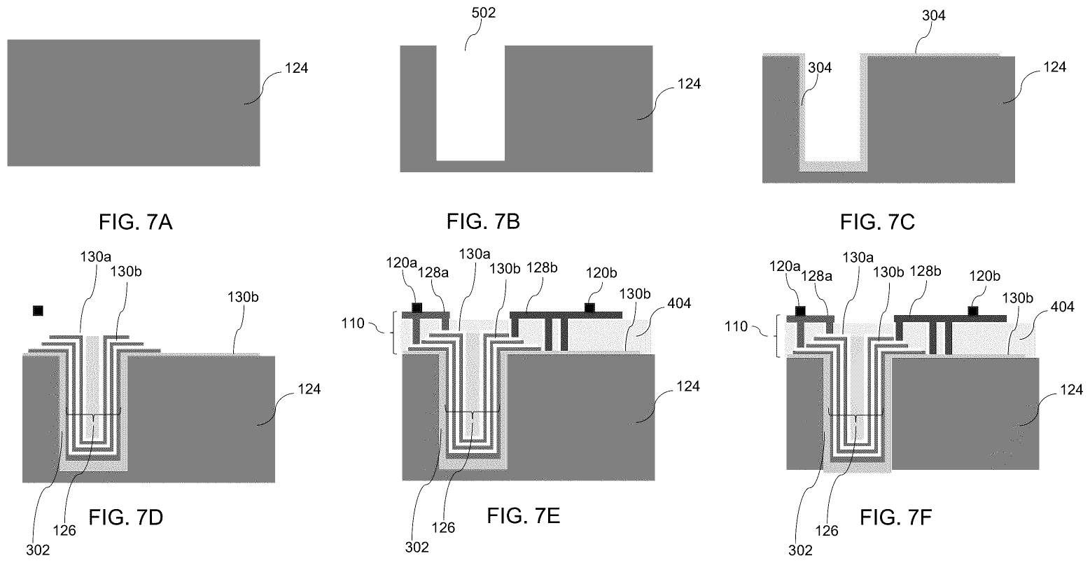

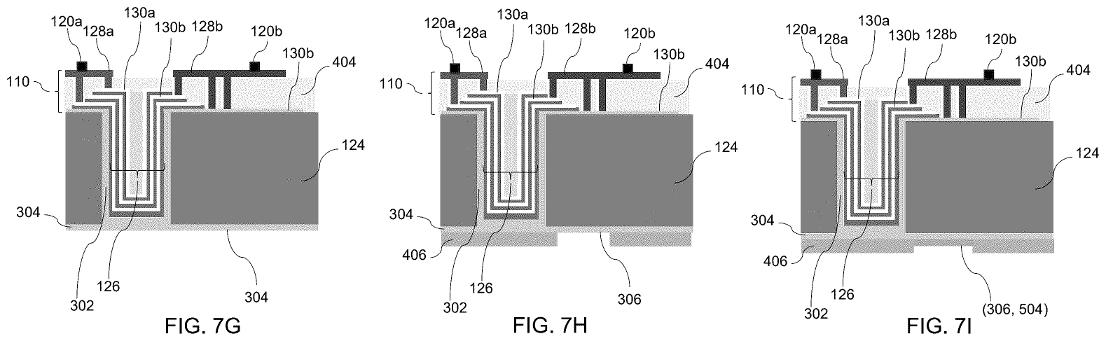

FIGS. 7A to 7I are vertical cross-sectional views of intermediate structures that may be used in the formation of an IPD 107c of FIG. 4C, according to various embodiments. As shown in FIG. 7B, the semiconductor substrate 124 of FIG. 7A may be etched to form a trench 502. The trench 502 may be similar to a trench (not shown) that may be used to form the deep trench capacitor 126 of FIGS. 5A to 6F. Prior to forming a deep trench capacitor 126, as shown in FIG. 7D, an electrically conducting material layer 304 may be deposited over the intermediate structure of FIG. 7B. As shown, the electrically conducting material layer 304 may be formed over the bottom and sidewalls of the trench 502 as well as over top surfaces of the semiconductor substrate 124.

A deep trench capacitor 126 may then be formed over the electrically conducting material layer 304 within the trench 502 by depositing alternating layers of dielectric material and electrically conducting material, as shown in FIG. 7D. As such, the electrically conducting material layer 304 may be configured as the lowest electrically conducting layer of the deep trench capacitor 126. Similarly, the portion of the electrically conducting layer 304 formed over top surfaces of the semiconductor substrate 124 may be configured as a ground terminal 130b of the deep trench capacitor 126. A redistribution layer 110 including first interconnects 128a and second interconnects 128b may then be formed over the intermediate structure of FIG. 7D to thereby form the intermediate structure of FIG. 7E. Then, as shown in FIG. 7F, a grinding process may be performed to remove a portion of the bottom surface of the semiconductor substrate 124 to thereby reveal a surface of the electrically conducting material layer 304 on the bottom side of the intermediate structure of FIG. 7F.

As shown in FIG. 7G, an additional electrically conducting material layer 304 may be deposited on the bottom side of the semiconductor substrate 124. A polymer layer 406 may then be deposited over the bottom side of the electrically conducting material layer 304. The polymer layer 406 may then be patterned to expose of portion of the electrically conducting material layer 304 that may be configured as an electrical contact structure 306, as shown in FIG. 7H. The intermediate structure of FIG. 7I may be formed from the intermediate structure of FIG. 7H by forming an additional conducting material layer 504 formed over the exposed portion (i.e., the electrical contact structure 306) of the electrically conducting material layer 304. The additional conducting material layer 504 may include tin, nickel, or other plating material and may be formed by electroplating, sputtering, or other vapor phase deposition technique. The methods of FIG. 5A-5I may be modified to form the IPD 107d (e.g., see FIG. 4D). In a similar manner the methods of FIG. 6A-6F may be modified to form the IPD 107e (e.g., see FIG. 4E). for example, the depth of the trench 502 may modified and formed after the formation of the redistribution layer 110 that may include first interconnects 128a and second interconnects 128b formed in a dielectric layer 404.

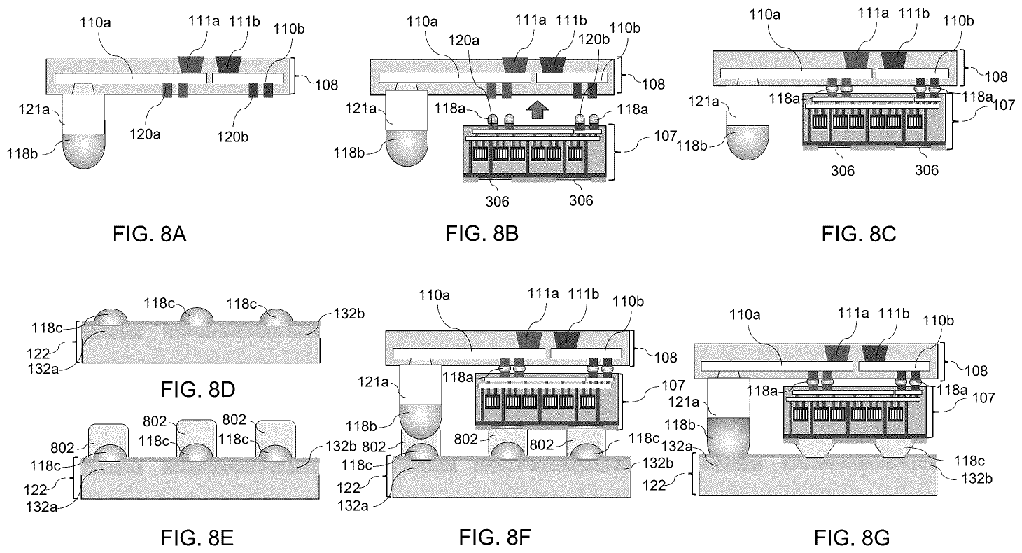

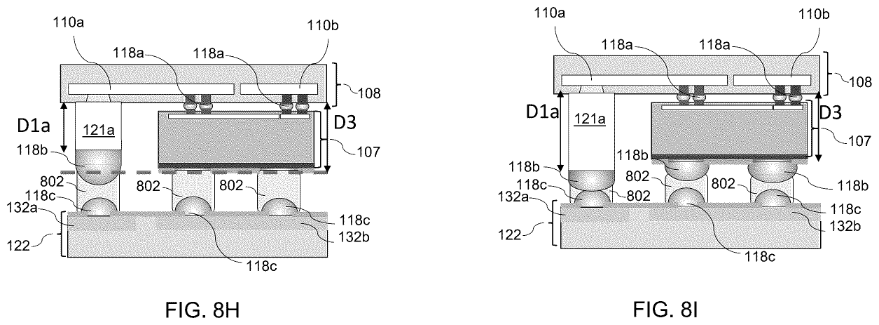

FIGS. 8A to 8I are vertical cross-sectional views of intermediate structures that may be used in the formation of a semiconductor package (200, 300a, 300b). The first intermediate structure of FIG. 8A may include an interposer 108 having a first bump structure 121a with a second solder material portion 118b attached thereto. The interposer 108 may include bonding pads (120a, 120b) (or bump structures) that may be configured to allow bonding of an IPD 107 to the interposer 108. As shown in FIG. 800b, an IPD 107 may be brought into proximity of the interposer 108. Bonding pads (120a, 120b) (or bump structures) of the IPD 107 may include first solder material portions 118a attached to the bonding pads (120a, 120b). The bonding pads (120a, 120b) of the IPD 107 may be aligned with corresponding bonding pads (120a, 120b) of the interposer 108. A reflow operation may then be performed to melt the first solder material portions 118a. Upon cooling, the first solder material portions 118a may then re-solidify and may thereby form electrical and mechanical connections between the IPD 107 and the interposer 108 to form the intermediate structure of FIG. 8C.

The intermediate structure of FIG. 8C may then be electrically and mechanically attached to a package substrate 122, as shown in FIG. 8G. As shown in FIG. 8C, the IPD 107 may include electrical contact structures 306 on a second side of the IPD 107 opposite to interposer 108, as described above (e.g., see FIGS. 4A to 4E). As such, the electrical contact structures 306 may be electrically and mechanically attached to the package substrate 122, in addition to coupling the first bump structure 121a to the package substrate 122. As shown in FIG. 8D, third solder material portions 118c may be formed on package substrate electrical contacts (132a, 132b) of the package substrate 122. Additional solder paste 802 may also be formed over the third solder material portions 118c. As shown in FIG. 8F, the intermediate structure of FIG. 8C may be aligned over the package substrate 122. A reflow process may then be performed to melt the second solder material portions 118b, the solder paste 802, and the third solder material portions 118c. Upon cooling, the second solder material portions 118b, the solder paste 802, and the third solder material portions 118c may re-solidify to thereby form electrical and mechanical connections between the IPD 107 and the package substrate 122 and between the first bump structure 121a and the package substrate 122.

As shown in FIGS. 8H and 8I, the first bump structure 121a and the IPD 107 may extend to different distances from a bottom surface of the interposer 108. For example, in the intermediate structure of FIG. 8H, the first bump structure 121a may extend to a distance D1a that is less than a distance D3 to which the IPD 107 extends from the bottom surface of the interposer 108. Alternatively, in the intermediate structure of FIG. 8I, the first bump structure 121a may extend to a distance D1a that is greater than a distance D3 to which the IPD 107 extends from the bottom surface of the interposer 108. In each intermediate structure of FIGS. 8H and 8I, the differences between D1a and D3 may be accommodated by a thickness of the solder paste 802 portions provided, for example, in the intermediate structure of FIG. 8E.

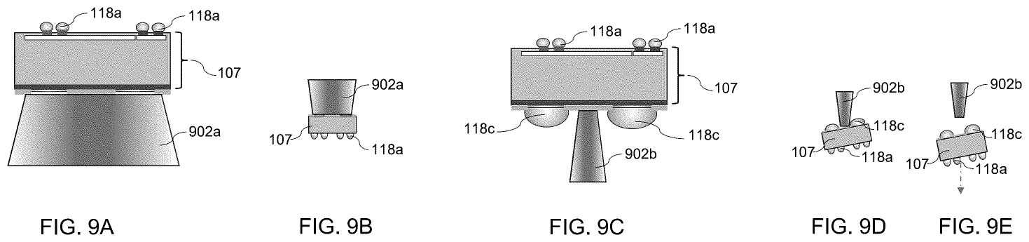

FIG. 9A is a vertical cross-sectional view of an IPD 107 that is held by a pick-and-place tool 902a, and FIG. 9B is a further vertical cross-sectional view of the IPD 107 that is held by the pick-and-place tool 902a of FIG. 9A, according to various embodiments. As shown in FIGS. 9A and 9B, the pick-and-place tool may have a width that is comparable to a width of the IPD 107. As such, the pick-and-place tool 902a may hold the IPD 107 securely such that the IPD 107 is unlikely to be dropped even when held upside down, as shown in FIG. 9B.

FIGS. 9C to 9E are vertical cross-sectional views of an alternative pick-and-place tool 902b in a comparative embodiments. As shown, the alternative pick-and-place tool 902b may be narrower than the embodiment pick-and-place tool 902a of FIGS. 9A and 9B. In this regard, the alternative IPD 107 may include first solder material portions 118a on a top side of the IPD 107 and third solder material portions 118c on the bottom side of the IPD 107. The presence of the third solder material portions 118c provides a geometric constraint that is not present in the embodiment of FIGS. 9A and 9B that may require the alternative pick-and-place tool 902b to be narrower than then the embodiment pick-and-place tool 902a of FIGS. 9A and 9B. This geometric constraint may be disadvantageous in that the pick-and-place tool 902b of FIGS. 9C, 9D, and 9E may provide a less secure connection between the IPD 107 and the pick-and-place tool 902b that may lead to the IPD 107 being dropped, as shown in FIG. 9E. Thus, as described above with reference to FIGS. 8D, 8E, 8F, and 8G, it may be more advantageous to provide the third solder material portions 118c only on the package substrate 122 and not on the bottom side of the IPD 107.

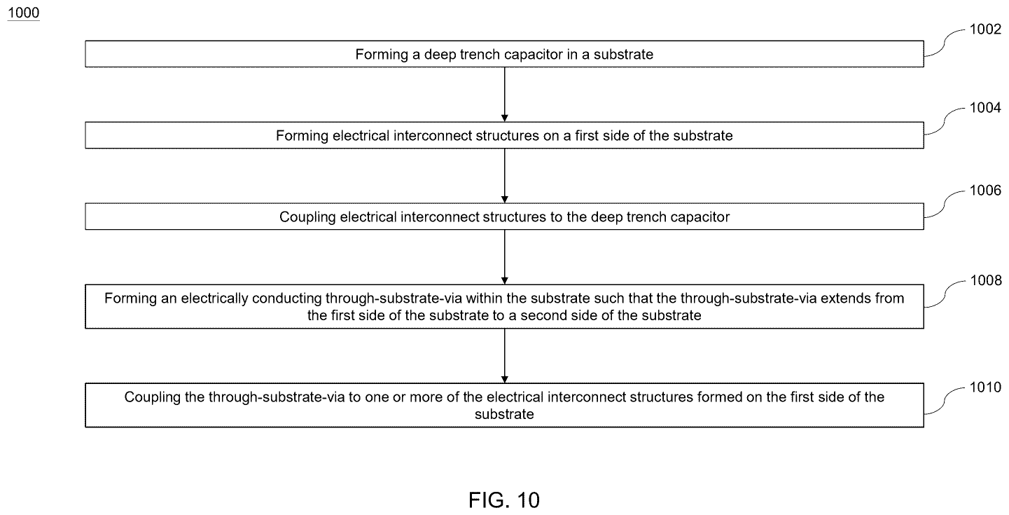

FIG. 10 is a flowchart illustrating operations of a method 1000 of forming an IPD (107a, 107b, 107c, 107d, 107e), according to various embodiments. In operation 1002, the method 1000 may include forming a deep trench capacitor 126 in a substrate 124. In operation 1004, the method 1000 may include forming electrical interconnect structures (128a, 128b) on a first side of the substrate 124. In operation 1006, the method 1000 may include coupling electrical interconnect structures (128a, 128b) to the deep trench capacitor 126. In operation 1008, the method 1000 may include forming an electrically conducting through-substrate-via 302 within the substrate 124 such that the through-substrate-via 302 extends from the first side of the substrate 124 to a second side of the substrate 124. In operation 1010, the method 1000 may include coupling the through-substrate-via 302 to one or more of the electrical interconnect structures (128a, 128b) formed on the first side of the substrate 124.

The method 1000 may further include forming an electrically conducting material layer 304 on the second side of the substrate 124 that is formed in direct contact with the substrate 124 and that is electrically connected to the through-substrate-via 302; forming a polymer layer 406 over the electrically conducting material layer 304; and forming an opening in the polymer layer 406 that exposes a portion of the electrically conducting material layer 304 such that an exposed portion of the electrically conducting material layer 304 is formed as an electrical contact structure 306 on the second side of the substrate 124.

In forming the through-substrate-via 302 according to operation 1008, the method 1000 may further include forming the through-substrate-via 302 as an electrically conducting shell structure 302 around the deep trench capacitor 126 that extends from the first side of the substrate 124 to the second side of the substrate 124. In addition, in forming the through-substrate-via 302 according to operation 1008, the method 1000 may further include forming the through-substrate-via 302 as a composite structure including an electrically conducting shell structure 302 surrounding a non-conducting polymer material 406, such that the electrically conducting shell structure 302 is separate and distinct from the deep trench capacitor 126.

Referring to all drawings and according to various embodiments of the present disclosure, an IPD (107a, 107b, 107c, 107d, 107e) is provided. The IPD (107a, 107b, 107c, 107d, 107e) may include a substrate 124, a deep trench capacitor 126 formed within the substrate 124, electrical interconnect structures (128a, 128b) formed on a first side of the substrate 124 and electrically connected to the deep trench capacitor 126, and an electrically conducting through-substrate-via 302 formed within the substrate 124. The electrically conducting through-substrate-via 302 may be formed so as to extend from the first side of the substrate 124 to a second side of the substrate 124 and may be electrically connected to one or more of the electrical interconnect structures (128a, 128b) formed on the first side of the substrate 124. The electrical interconnect structures (128a, 128b) may further include first interconnects 128a connected to one or more power terminals 130a of the deep trench capacitor 126 and second interconnects 128b connected to one or more ground terminals 130b of the deep trench capacitor 126, and the through-substrate-via 302 may be electrically connected to the second interconnects 128b on the first side of the substrate 124.

The IPD (107a, 107b, 107c, 107d, 107e) may further include an electrical contact structure 306 formed on the second side of the substrate 124 that is electrically connected to the through-substrate-via 302. According to various embodiments, the through-substrate-via 302 may be formed as an electrically conducting shell structure 302 around the deep trench capacitor 126 that extends from the first side of the substrate 124 to the second side of the substrate 124. According to further embodiments, the through-substrate-via 302 may be formed as a composite structure including an electrically conducting shell structure 302 surrounding a non-conducting polymer material 402, and the electrically conducting shell structure 302 may be separate and distinct from the deep trench capacitor 126 (e.g., see FIGS. 4B and 4E). In some embodiments, the through-substrate-via 302 may be formed as volume of electrically conducting material extending through the substrate 124 (e.g., see FIGS. 4A and 4D).

The IPD (107a, 107b, 107c, 107d, 107e) may further include a dielectric layer 402 formed on the first side of the substrate 124 such that the electrical interconnect structures (128a, 128b) are formed within the dielectric layer 402. Further, the through-substrate-via 302 may extend from the second side of the substrate 124, through the first side of the substrate 124, and through at least a portion of the dielectric layer 402. In various embodiments, the electrical interconnect structures (128a, 128b) may be formed as redistribution layers 110 that further include micro-bump electrical contacts (120a, 120b) such that the micro-bump electrical contacts (120a, 120b) are electrically connected to respective power terminals 130a and ground terminals 130b of the IPD (107a, 107b, 107c, 107d, 107e). Further, the substrate 124 may include silicon and the through-substrate-via 302 may include an electrically conducting material that is formed in direct contact with the substrate 124.

In various embodiments, the IPD (107a, 107b, 107c, 107d, 107e) may further include an electrically conducting material layer 304 formed on the second side of the substrate 124 that is formed in direct contact with the substrate 124 and that is electrically connected to the through-substrate-via 302. The IPD (107a, 107b, 107c, 107d, 107e) may further include a polymer layer 406 formed over the electrically conducting material layer 304 and an opening in the polymer layer 406 that exposes a portion of the electrically conducting material layer 304 such that an exposed portion of the electrically conducting material layer 304 is formed as an electrical contact structure 306 on the second side of the substrate 124. In various embodiments, the IPD (107a, 107b, 107c, 107d, 107e) may further include a tin plating layer 504 formed over the exposed portion of the electrically conducting material layer 304, such that the electrically conducting material layer 304 and the through-substrate-via 302 include copper.

Referring to all drawings and according to various embodiments of the present disclosure, semiconductor package structure (300a, 300b) is provided. The semiconductor package structure (300a, 300b) may include an interposer 108, a package substrate 122, and an IPD (107a, 107b, 107c, 107d, 107e) sandwiched therebetween, and electrically connected to, the interposer 108 and the package substrate 122.

According to various embodiments, the IPD 107 may include an IPD substrate 124, a deep trench capacitor 126 formed within the IPD substrate 124, and an electrically conducting through-substrate-via 302 formed within the IPD substrate 124. The through-substrate-via 302 may extend from a first side of the IPD substrate 124 to a second side of the IPD substrate 124 such that the through-substrate-via 302 is electrically connected to the deep trench capacitor 126 on the first side of the IPD substrate 124 and may be electrically connected to the package substrate 122 on the second side of the IPD substrate 124. In various embodiments, the IPD 107 may further include electrical interconnect structures (128a, 128b) formed on the first side of the IPD substrate 124 that are electrically connected to the deep trench capacitor 126, and micro-bump electrical contacts (120a, 120b) connected to the electrical interconnect structures (128a, 128b), such that the micro-bump electrical contacts (120a, 120b) are electrically connected to the interposer 108.

According to various embodiments, the IPD 107 may further include an electrically conducting material layer 304 formed on the second side of the IPD substrate 124 that is formed in direct contact with the IPD substrate 124 and that is electrically connected to the through-substrate-via 302, an electrical contact structure 306 formed on the second side of the IPD substrate 124 that is electrically connected to the through-substrate-via 302, and a solder material portion 118c formed between the electrical contact structure 306 of the IPD 107 and a corresponding package substrate electrical contact 132b such that the IPD 107 is electrically connected to the package substrate 122.

According to various embodiments, the electrical interconnect structures (128a, 128b) may further include first interconnects 128a connected to one or more power terminals 130a of the deep trench capacitor 126 and second interconnects 128b connected to one or more ground terminals 130b of the deep trench capacitor 126 and at least one of the micro-bump electrical contacts (120a, 120b) is connected to the second interconnects 128b and further connected to a first ground contact 110b of the interposer 108. Further, the electrical contact structure 306 of the IPD 107 may be connected to a second ground contact 132b of the package substrate 122 such that the interposer 108, the IPD 107, and the package substrate 122 include a common ground connection that is electrically connected to the through-substrate-via 302.

Various embodiments disclosed herein may be advantageous by providing an IPD 107 having a through-substrate-via 302 that provides a common electrical ground connection on a first side and on a second side of the IPD 107. As such, the IPD 107 may be electrically connected to an interposer 108 on the first side of the IPD 107 and electrically connected to a package substrate 122 on the second side of the IPD 107. The direct electrical connections on both the first and second sides of the IPD 107 provide ground electrical pathways having shorter lengths than corresponding electrical pathways in IPDs 107 that only provide electrical connections on the first side of the IPD 107. Such shorter electrical pathways may provide reduced electrical loss and lower signal delays by reducing an RC time constant associated with the shorter electrical pathways.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. An integrated passive device, comprising:
a substrate;
a deep trench capacitor formed within the substrate;
electrical interconnect structures formed on a first side of the substrate and electrically connected to the deep trench capacitor; and
an electrically conducting through-substrate-via formed within the substrate and extending from the first side of the substrate to a second side of the substrate and electrically connected to one or more of the electrical interconnect structures formed on the first side of the substrate.

2. The integrated passive device of claim 1, wherein:
the electrical interconnect structures further comprise first interconnects connected to one or more power terminals of the deep trench capacitor and second interconnects connected to one or more ground terminals of the deep trench capacitor; and
the through-substrate-via is electrically connected to the second interconnects on the first side of the substrate.

3. The integrated passive device of claim 2, further comprising:
an electrical contact structure formed on the second side of the substrate that is electrically connected to the through-substrate-via.

4. The integrated passive device of claim 3, wherein:
the through-substrate-via is formed as an electrically conducting shell structure around the deep trench capacitor that extends from the first side of the substrate to the second side of the substrate.

5. The integrated passive device of claim 3, wherein:
the through-substrate-via is formed as a composite structure comprising an electrically conducting shell structure surrounding a non-conducting polymer material; and
the electrically conducting shell structure is separate and distinct from the deep trench capacitor.

6. The integrated passive device of claim 3, wherein:
the through-substrate-via is formed as volume of electrically conducting material extending through the substrate.

7. The integrated passive device of claim 1, further comprising:
a dielectric layer formed on the first side of the substrate,
wherein:
the electrical interconnect structures are formed within the dielectric layer; and
the through-substrate-via extends from the second side of the substrate, through the first side of the substrate, and through at least a portion of the dielectric layer.

8. The integrated passive device of claim 1, wherein the electrical interconnect structures are formed as redistribution layers that further comprise micro-bump electrical contacts such that the micro-bump electrical contacts are electrically connected to respective power terminals and ground terminals of the integrated passive device.

9. The integrated passive device of claim 1, wherein:
the substrate comprises silicon; and
the through-substrate-via comprises an electrically conducting material that is formed in direct contact with the substrate.

10. The integrated passive device of claim 9, further comprising:
an electrically conducting material layer formed on the second side of the substrate that is formed in direct contact with the substrate and that is electrically connected to the through-substrate-via.

11. The integrated passive device of claim 10, further comprising:
a polymer layer formed over the electrically conducting material layer; and
an opening in the polymer layer that exposes a portion of the electrically conducting material layer such that an exposed portion of the electrically conducting material layer is formed as an electrical contact structure on the second side of the substrate.

12. The integrated passive device of claim 11, further comprising:
a tin plating layer formed over the exposed portion of the electrically conducting material layer, wherein the electrically conducting material layer and the through-substrate-via comprise copper.

13. A semiconductor package structure, comprising:
an interposer;
a package substrate; and
an integrated passive device (IPD) sandwiched therebetween, and electrically connected to, the interposer and the package substrate,
wherein the IPD comprises:
an IPD substrate;
a deep trench capacitor formed within the IPD substrate; and
an electrically conducting through-substrate-via formed within the IPD substrate and extending from a first side of the IPD substrate to a second side of the IPD substrate such that the through-substrate-via is electrically connected to the deep trench capacitor on the first side of the IPD substrate and is electrically connected to the package substrate on the second side of the IPD substrate.

14. The semiconductor package structure of claim 13, wherein the IPD further comprises:
electrical interconnect structures formed on the first side of the IPD substrate that are electrically connected to the deep trench capacitor; and
micro-bump electrical contacts connected to the electrical interconnect structures, wherein the micro-bump electrical contacts are electrically connected to the interposer.

15. The semiconductor package structure of claim 14, wherein the IPD further comprises:
an electrically conducting material layer formed on the second side of the IPD substrate that is formed in direct contact with the IPD substrate and that is electrically connected to the through-substrate-via;
an electrical contact structure formed on the second side of the IPD substrate that is electrically connected to the through-substrate-via; and
a solder material portion formed between the electrical contact structure of the IPD and a corresponding package substrate electrical contact such that the IPD is electrically connected to the package substrate.

16. The semiconductor package structure of claim 15, wherein
the electrical interconnect structures further comprise first interconnects connected to one or more power terminals of the deep trench capacitor and second interconnects connected to one or more ground terminals of the deep trench capacitor;
at least one of the micro-bump electrical contacts is connected to the second interconnects and further connected to a first ground contact of the interposer; and
the electrical contact structure of the IPD is connected to a second ground contact of the package substrate such that the interposer, the IPD, and the package substrate comprise a common ground connection that is electrically connected to the through-substrate-via.

17. A method of forming an integrated passive device, comprising:
forming a deep trench capacitor in a substrate;
forming electrical interconnect structures on a first side of the substrate;
coupling the electrical interconnect structures to the deep trench capacitor;
forming an electrically conducting through-substrate-via within the substrate such that the through-substrate-via extends from the first side of the substrate to a second side of the substrate; and
coupling the through-substrate-via to one or more of the electrical interconnect structures formed on the first side of the substrate.

18. The method of claim 17, further comprising:
forming an electrically conducting material layer on the second side of the substrate that is formed in direct contact with the substrate and that is electrically connected to the through-substrate-via;
forming a polymer layer over the electrically conducting material layer; and
forming an opening in the polymer layer that exposes a portion of the electrically conducting material layer such that an exposed portion of the electrically conducting material layer is formed as an electrical contact structure on the second side of the substrate.

19. The method of claim 17, wherein forming the through-substrate-via further comprises:
forming the through-substrate-via as an electrically conducting shell structure around the deep trench capacitor that extends from the first side of the substrate to the second side of the substrate.

20. The method of claim 17, wherein forming the through-substrate-via further comprises:
forming the through-substrate-via as a composite structure comprising an electrically conducting shell structure surrounding a non-conducting polymer material, such that the electrically conducting shell structure is separate and distinct from the deep trench capacitor.
